(19) United States
(12) Patent Application Publication
(10) Pub. No.: US 2026/0049389 A1
(43) Pub. Date: Feb. 19, 2026

(54) PREPARATION METHOD OF ALUMINUM NITRIDE SUBSTRATE

(71) Applicant: National Chung Shan Institute of Science and Technology, Taoyuan (TW)

(72) Inventors: Chung-Yen Lu, Taoyuan (TW); Jian-Long Ruan, Taoyuan (TW); Cheng-Hung Shih, Taoyuan (TW)

(21) Appl. No.: 18/806,727

(22) Filed: Aug. 16, 2024

(51) Int. Cl. C23C 14/35; C23C 14/04; C23C 14/58

(52) U.S. Cl. CPC C23C 14/35; C23C 14/046; C23C 14/5846; C23C 14/5873

(57) ABSTRACT

A method for preparing an AlN substrate includes: (A) providing a surface-polished polycrystalline aluminum nitride (AlN) substrate; (B) forming a first AlN film via reactive sputtering using magnetron sputtering with an aluminum target, nitrogen, and argon gases to fill surface lattice defect pores; (C) removing the first AlN film by thinning and polishing, leaving filled pore areas to form a planar AlN substrate; (D) sintering the planar substrate at high temperature to enhance adhesion; (E) forming a second AlN film on the sintered AlN substrate; (F) removing the second AlN film by thinning and polishing to achieve a final AlN substrate with high thermal conductivity and low surface pore sizes.

### BACKGROUND

### Technical Field

The present invention relates to a method for preparing a high thermal conductivity aluminum nitride (AlN) substrate with low surface pore sizes, specifically relates to a method for reducing the surface pore size of polycrystalline AlN substrates.

### Description of Related Art

Aluminum nitride (AlN) ceramic substrates offer high thermal dissipation, long lifespan, low thermal resistance, and voltage resistance. With improvements in production technology and equipment, AlN ceramic substrates have expanded applications in high-power LED industries, enhancing the performance, reliability, and lifespan of high-power lighting components. Therefore, they are a key material for the next generation of high-power devices. Currently, high-power LED substrates primarily use low thermal conductivity alumina. However, the significant heat generated by high-power LEDs and power semiconductor components demands stringent thermal shock resistance from the products.

Aluminum nitride (AlN) is a ceramic insulator with high thermal conductivity (polycrystalline thermal conductivity ranges from about 70-210 W·m⁻¹·K⁻¹), making it widely used in microelectronics. With improvements in production technology and processing equipment, AlN ceramic substrates, which also offer low thermal resistance and voltage resistance, can be applied in high-power LED lighting industries, enhancing the performance and reliability of high-power lighting products.

To enhance the reliability and value-added applications of high-power components, it is necessary to fill the surface pores of high thermal conductivity aluminum nitride (AlN) substrates to reduce surface defects. This not only improves thermal conductivity but also benefits the development of miniaturized semiconductor and electronic components. Given these needs, it is essential to develop optimization technologies for surface defects of high thermal conductivity AlN substrates. Key technical challenges include: (1) Surface filling materials: including chemical purity and material types; (2) Surface filling processes: including vacuum coating technology and monitoring techniques; (3) Filling integration techniques: including enhancing bond strength and density of filling materials; (4) Surface optimization techniques: including grinding, rough polishing, and fine polishing. Surface pores on substrates not only highly correlate with reflectivity in reflective substrates of optical elements but also hinder the development of high-power semiconductor and electronic products that require high thermal dissipation, high insulation, and increasingly precise manufacturing processes.

Methods for preparing aluminum nitride (AlN) films primarily include Chemical Vapor Deposition (CVD), Molecular Beam Epitaxy (MBE), Plasma-Assisted Chemical Vapor Deposition (PACVD), Laser Chemical Vapor Deposition (LCVD), Metal-Organic Chemical Vapor Deposition (MOCVD), Pulsed Laser Deposition (PLD), Magnetron Reactive Sputtering (MRS), and Ion Implantation. Magnetron sputtering accelerates ions in the plasma, causing them to contact the metal or inorganic compound target, resulting in energetic target ions being sputtered onto the oobject component. This process increases the kinetic energy of the coating molecules, improving the film's density and adhesion and reducing process time, effectively enhancing productivity.

In high-power light-emitting device heat dissipation substrates, the need for increased thermal dissipation presents challenges. Compared to substrates made of glass, PET, and alumina ceramics, which have lower thermal conductivity and thus poorer heat dissipation, using higher-cost materials like sapphire and silicon carbide leads to significantly increased costs. These substrates struggle to simultaneously meet the requirements of high thermal conductivity, high insulation, easy surface processing, and cost-effectiveness when applied to high-power light-emitting devices.

Previous literature, specifically patent CN 106431419, proposed a method for preparing high thermal conductivity aluminum nitride (AlN) ceramic substrates for high-power microelectronic devices. This method includes the following steps: (1) Formulation: obtaining high-purity AlN powder mixed with yttrium oxide (or yttria) as a sintering aid, uniformly mixed in an organic solvent and additives. (2) Production: combining tape casting with isostatic pressing to form green bodies. (3) Degreasing: removing grease using a hydrogen/nitrogen gas mixture. (4) Sintering: conducting atmospheric pressure sintering of the degreased green bodies.

While this patent's method modifies the initial preparation process. From adjusting the ratio of sintering aids to optimizing the atmosphere during glue removing and sintering after forming the green bodies, these modifications can produce high thermal conductivity AlN substrates. However, this method does not specifically address the subsequent surface pore treatment optimization for polycrystalline ceramic substrates. During the sintering process, lattice defects can create pores, reducing substrate strength and thermal conductivity, and decreasing surface flatness. This directly impacts the efficiency of high-power semiconductor processing and optical reflector applications. Therefore, maintaining high thermal conductivity while optimizing surface pore filling is crucial for enhancing the substrate's application value.

In the manufacturing process of certain power electronic components, it is necessary to create conductive circuits on both sides of ceramic substrates. To achieve double-sided circuit connectivity, holes must be drilled in the ceramic substrate, which are then filled with metal conductive paste or by direct copper electroplating to establish electrical connectivity between the upper and lower metal circuits. Many patents on ceramic surface metallization and hole filling focus on creating conductive holes and using conductive metal columns for filling, such as the method disclosed in patent CN 115460798 B. This patent addresses filling tiny conductive holes in ceramic substrates for semiconductor power device processing, proposing solutions to prevent bubbles or voids during metal line filling, which would otherwise reduce electroplating efficiency. However, this method is only applicable to metals with conductive properties during the filling process and is mainly used in substrate metallization. It differs from the present invention, which aims to optimize the surface flatness of aluminum nitride substrates by filling holes with the same material. Moreover, since aluminum nitride is an insulator, electroplating cannot be used for surface hole filling.

Group III-V materials often face difficulties in growing or depositing on external substrates without forming crystal defects or cracks. In many applications, such as high-power power supplies, LEDs, or integrated circuits, it is challenging to avoid damage and defects during the fabrication of sensitive III-V films. Patent CN104428441 B provides a method for forming aluminum nitride buffer and active layers using physical vapor deposition (PVD). This method optimizes the PVD process to deposit aluminum nitride buffer layers with high crystal orientation on one or multiple substrate surfaces simultaneously in one or multiple chambers. It addresses issues arising from material properties and lattice mismatches during heteroepitaxial growth on modified sapphire or silicon substrates with Group III nitride layers, which can lead to defect propagation and poor process quality. In contrast, the aluminum nitride film produced on AlN substrates in this invention is primarily used to repair surface pores of AlN substrates, thus not requiring high crystal orientation. The sputtering parameters for the aluminum nitride film are simpler, without the need for complex heat treatments and coating processes in multiple chambers.

Patent CN109867521A describes a method for secondary modification and densification of oxide ceramic films. This method addresses incompletely dense oxide ceramic substrates by treating them with a secondary phase solution. Capillary action is used to fill the gaps, and a low-temperature sintering aid is introduced to modify the interfaces of the pores in the incompletely dense oxide ceramic film. The film is then subjected to secondary sintering to achieve densification and improve performance. This densified oxide ceramic film technology is primarily applied in solid oxide fuel cells, serving as a barrier layer between the stabilized electrolyte in oxide ceramic substrate and the porous anode, preventing high-temperature reactions between the electrolyte and anode materials. In this method, capillary action is used to introduce the low-temperature sintering aid, and the process involves 2-5 cycles of dipping in the modification solution and drying, with each drying cycle lasting 2-8 hours. The secondary sintering then is used to fill the surface pores of the film. Although this method effectively enhances film densification, the thermal treatment process is lengthy and complex, which can also lead to a loss of surface flatness, making it more advantageous for non-planar items. In the present invention, since the surface of the aluminum nitride substrate is planar, reactive magnetron sputtering technology is used. High-energy target ions form a dense aluminum nitride film upon contact with the surface of the polycrystalline aluminum nitride substrate. This, combined with high-temperature sintering and surface grinding and polishing processes, can repair surface pores of the AlN substrate while slightly improving thermal conductivity and bending strength.

Therefore, there is a need in the industry for a method to prepare high thermal conductivity polycrystalline aluminum nitride (AlN) substrates with low surface pore sizes. Such substrates must simultaneously offer high thermal conductivity, high insulation, low surface pore sizes, and low porosity. Using a simple process to produce substrates with high thermal dissipation, high insulation, and low porosity will not only benefit the development of miniaturized processes in high-power electronic components but also have significant potential for future applications in optical elements requiring high thermal dissipation and high-power semiconductor chips.

### SUMMARY

In view of the shortcomings of the aforementioned conventional technologies, an aspect of this invention is to provide a method for preparing high thermal conductivity aluminum nitride (AlN) substrates with low surface pore sizes. The process includes surface grinding, polishing, high-temperature sintering, two stages of polishing and double-layer aluminum nitride film deposition to fill pores. This method can produce polycrystalline AlN substrates with excellent thermal dissipation, low cost, and low surface pore sizes.

To enhance the application value of aluminum nitride (AlN) substrates and meet the requirements for high thermal conductivity, high insulation, surface flatness, ease of processing, and low cost, a method for preparing high thermal conductivity AlN substrates with low surface pore sizes has been developed. The process uses surface-polished polycrystalline AlN as the substrate material. A first AlN film is used to fill surface defects on the substrate, followed by high-temperature sintering to enhance the adhesion and density of the filled pores. After grinding and polishing, a second AlN film is deposited for a second surface pore filling. This is followed by a second grinding and polishing step to complete the fabrication. This invention allows for the simple and rapid preparation of AlN substrates with high thermal conductivity, high insulation, and low surface pore sizes, suitable for high thermal dissipation optical components and high-power semiconductor electronic products.

To achieve the above aspects, according to one embodiment of the present invention, a method for preparing high thermal conductivity aluminum nitride (AlN) substrates with low surface pore sizes is provided. The method comprises the following steps. (A) A surface-polished polycrystalline aluminum nitride (AlN) substrate is provided. (B) A first surface pore-filling step is performed by forming a first AlN film on a surface of the AlN substrate to fill lattice defect pores on the surface of the AlN substrate, wherein the first AlN film is formed by plasma for reactive sputtering and the plasma is formed by a magnetron sputtering equipment with an aluminum (Al) target, nitrogen gas, and argon gas. (C) The first AlN film formed in step (B) is removed by thinning and polishing to leave filled portions within the lattice defect pores to form a planar AlN substrate. (D) The planar AlN substrate is sintered under high-temperature to enhance the adhesion of the AlN film within the lattice defect pores with the substrate. (E) A second surface pore-filling step is performed by forming a second AlN film on the sintered AlN substrate. (F) The second AlN film formed in step (E) is removed by thinning and polishing to leave filled portions within the lattice defect pores to form a final AlN substrate with high thermal conductivity and low surface pore sizes.

According to an embodiment of this invention, the surface-polished polycrystalline aluminum nitride (AlN) substrate in step (A) is prepared by a doctor blade forming method or a high-temperature sintering and cutting forming method. The surface-polished polycrystalline AlN substrate in step (A) has a thermal conductivity of at least 170 W·m⁻¹·K⁻¹ and a central line average roughness (Ra) of 20-30 nm.

According to an embodiment of this invention, the following steps performed before step (B) are further comprised. (1) The surface-polished polycrystalline AlN substrate is wiped with a solvent selected from acetone, alcohol, or isopropanol to remove surface dirt. (2) Organic residues and moisture are removed from the surface of the polycrystalline AlN substrate using oxygen ion plasma, wherein the oxygen ion plasma is generated by reactive ion etching (RIE) or inductively coupled plasma etching (ICP). In step (2), the oxygen ion plasma can be generated by reactive ion etching (RIE) or inductively coupled plasma (ICP) etching. The source gas for the oxygen ion plasma can be a mixture of oxygen and argon, with the oxygen/argon gas mixture ratio being 20%-30%. The process time is approximately 1 minute.

According to an embodiment of this invention, the plasma for preparing the first AlN film in step (B) is formed from the nitrogen gas, at a flow rate of 16-20 sccm, and the argon gas, at a flow rate of 40-48 sccm, under a vacuum with a pressure less than 5×10⁻⁸ torr and using a power of 1.5 KW, and then the plasma reacts with the Al target for 30-90 minutes to form the first AlN film with a thickness of 6-12 μm on the surface of the polycrystalline AlN substrate. The magnetron sputtering equipment is either DC direct current sputtering equipment or RF radio frequency magnetron sputtering equipment. The size of the lattice defect pores is smaller than 20 μm.

According to an embodiment of this invention, the thinning and polishing in step (C) or step (F) is performed by chemical mechanical polishing or physical mechanical polishing.

According to an embodiment of this invention, the thinning and polishing in step (C) or step (F) for removing the first or second aluminum nitride film on the substrate surface is performed under conditions comprising using CMP80 (a nano-polishing liquid with a primary particle size of approximately 80 nm) to polish at a rotation speed of 40-60 rpm, a temperature of 20° C., and a processing pressure of 2.5 kg/cm² for 10-60 minutes; and then using CMP20 (a nano-polishing liquid with a primary particle size of approximately 20 nm) to polish at a rotation speed of 20-40 rpm, a temperature of 20° C., and a processing pressure of 2 kg/cm² for 10-60 minutes.

According to an embodiment of this invention, the high-temperature sintering in step (D) is performed under a nitrogen atmosphere at atmospheric pressure, a sintering temperature of 1750-1850° C., and a holding time of 2-4 hours, and then the sintered AlN substrate is cooled by natural furnace cooling. This process enhances the adhesion and density of the first AlN film with the substrate, maintaining the substrate's high thermal conductivity and bending-resistant strength.

According to an embodiment of this invention, the plasma for preparing the second AlN film in step (E) is formed from the nitrogen gas, at a flow rate of 16-20 sccm, and the argon gas, at a flow rate of 40-42 sccm, under a vacuum with a pressure less than 5×10⁻⁸ torr and using a power of 1.0-1.2 KW, and then the plasma reacts with the Al target for 30-60 minutes to form the first AlN film with a thickness of 5-10 μm on the surface of the polycrystalline AlN substrate. The sputtering rate for depositing the second AlN film is slower than the sputtering rate for depositing the first AlN film to increase the density of the second AlN film and the adhesion of the second AlN film to the substrate.

According to an embodiment of this invention, in step (F), the second aluminum nitride (AlN) film on the substrate is removed by thinning or grinding and polishing to leave the filled portions within the pores, thereby completing the preparation of the high thermal conductivity polycrystalline AlN substrate with low surface pore sizes.

The method for filling surface pore defects on polycrystalline aluminum nitride (AlN) substrates in this invention uses reactive magnetron sputtering technology to generate an amorphous AlN film on an AlN substrate with surface pore defects. By controlling specific ratios of nitrogen and argon gas concentrations to generate plasma, AlN is formed upon contact with the aluminum target and sputtered onto the polished surface of the polycrystalline AlN substrate. This AlN film effectively fills the surface pore defects of the polycrystalline AlN substrate. The AlN film outside the surface pores is then removed by grinding and polishing, leaving the AlN that fills the pore defects. This process effectively enhances the surface flatness of the polycrystalline AlN substrate and reduces surface pore sizes. Coupled with high-temperature sintering treatment, the density of the AlN filling the surface pores is improved, maintaining the substrate's thermal conductivity and bending-resistant strength. By using two layers of AlN films for filling and combined grinding and polishing processes, the diameter of most untreated pore defects on the AlN substrate surface, initially around 20 μm, can be reduced to about 5 μm. Additionally, by using different sputtering parameters, the surface filling rate and density of the AlN film filling the pores can be improved.

By reducing the surface pore sizes of polycrystalline aluminum nitride (AlN) substrates, the application value of the product can be significantly enhanced. This improvement not only makes the substrates more suitable for use in high-power reflective light-emitting substrates but also meets the demands for surface miniaturization in the development of integrated circuits on thin AlN substrates.

The foregoing presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later. Many of the attendant features will be more readily appreciated as the same becomes better understood by reference to the following detailed description considered in connection with the accompanying drawings.

### BRIEF DESCRIPTION OF THE DRAWINGS

FIG. 1 is a flowchart of the a method for preparing high thermal conductivity polycrystalline aluminum nitride (AlN) substrates with low surface pore sizes according to Embodiment 1 of this invention.

FIG. 2 is a schematic structural diagram of a high thermal conductivity polycrystalline aluminum nitride (AlN) substrates with low surface pore sizes formed by the method according to Embodiment 1 of the present invention.

FIG. 3 is a high-magnification optical microscope photo of a surface of a polycrystalline AlN substrate after polishing, according to Embodiment 1 of the present invention.

FIG. 4 is a cross-sectional electron microscope photo of the polycrystalline aluminum nitride (AlN) substrate after sputtering the first AlN film according to Embodiment 1 of the present invention.

FIG. 5 is a high-magnification optical microscope photo of the surface after sputtering and polishing the first AlN film according to Embodiment 1 of the present invention.

FIG. 6 is a high-magnification optical microscope photo of the AlN substrate after filling the pores with the first AlN film and high-temperature sintering according to Embodiment 1 of the present invention.

FIG. 7 is a high-magnification optical microscope photo of the AlN substrate surface after completing the second AlN film pore filling according to Embodiment 1 of the present invention.

FIG. 8 is a comparative electron microscope observation diagram showing, from left to right, the AlN substrate before pore filling, the AlN substrate after filling and polishing with the first AlN film, and the AlN substrate after filling and polishing with the second AlN film according to Embodiment 1 of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The present invention is a method for preparing high thermal conductivity polycrystalline aluminum nitride (AlN) substrates with low surface pore sizes. This method uses reactive magnetron sputtering technology to create a first layer of dense AlN film by sputtering high-energy target ions onto the surface of the polycrystalline AlN substrate. This first AlN film fills the fine pore defects on the substrate's surface. The first AlN film is then removed by grinding and polishing to leave AlN in the pore defects to enhance surface flatness. High-temperature sintering is then used to improve the adhesion between the AlN film filling the pore defects and the AlN substrate body. After sintering, a second AlN film is deposited at a slower sputtering rate to fill the pores, and the second AlN film is again removed to leave the AlN filling the pore defects. By using two AlN films with different sputtering rates and one high-temperature sintering process, the original pore defects are effectively repaired. Combined with two grinding and polishing steps, this method ensures that the AlN substrate surface achieves high flatness, high thermal conductivity, and high bending-resistant strength after filling the micro pore defects. This enhances the reflective efficiency of the AlN substrate for high-power optical coating reflector bases to improve its applicability and added value.

Please refer to FIG. 1, which is a flowchart of the a method for preparing high thermal conductivity polycrystalline aluminum nitride (AlN) substrates with low surface pore sizes according to Embodiment 1 of this invention. As shown in FIG. 1, the method comprises the following steps. In step S101, a surface-polished polycrystalline aluminum nitride (AlN) substrate is provided. In step S102, a first surface pore-filling step is performed by forming a first AlN film on a surface of the AlN substrate to fill lattice defect pores on the surface of the AlN substrate, wherein the first AlN film is formed by plasma for reactive sputtering and the plasma is formed by a magnetron sputtering equipment with an aluminum (Al) target, nitrogen gas, and argon gas. In step S103, the first AlN film formed in step S102 is removed by thinning and polishing to leave filled portions within the lattice defect pores to form a planar AlN substrate. In step S104, the planar AlN substrate is sintered under high-temperature to enhance the adhesion of the AlN film within the lattice defect pores with the substrate. In step S105, a second surface pore-filling step is performed by forming a second AlN film on the sintered AlN substrate under a slower sputtering rate. In step S106, the second AlN film formed in step S105 is removed by thinning and polishing to leave filled portions within the lattice defect pores to form a final AlN substrate with high thermal conductivity and low surface pore sizes.

Before step S102, the following steps may be further performed. (1) The surface-polished polycrystalline AlN substrate is wiped with a solvent selected from acetone, alcohol, or isopropanol to remove surface dirt. (2) Organic residues and moisture are removed from the surface of the polycrystalline AlN substrate by using oxygen ion plasma.

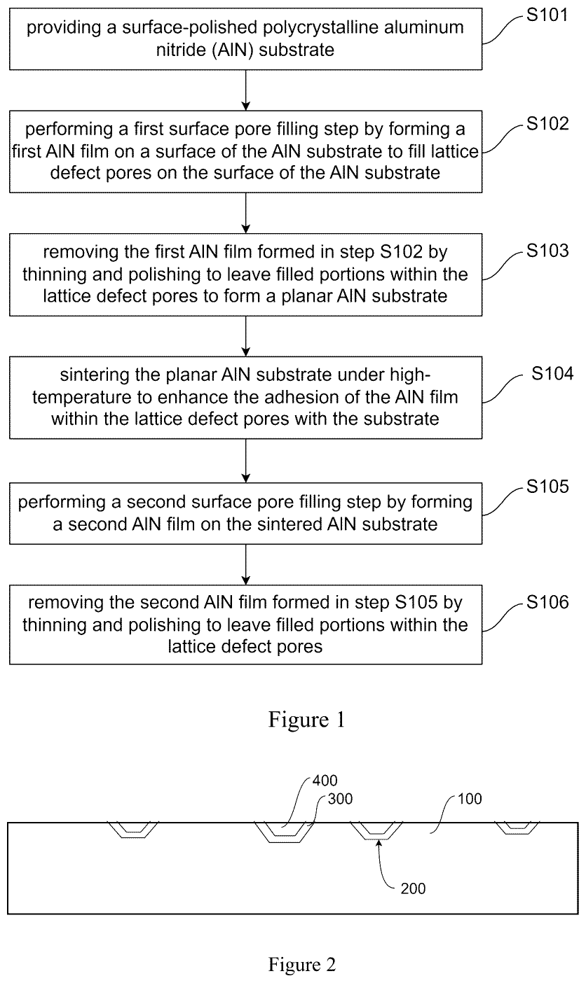

Please refer to FIG. 2, which is a schematic structural diagram of a high thermal conductivity polycrystalline aluminum nitride (AlN) substrates with low surface pore sizes formed by the method according to Embodiment 1 of the present invention. As shown in FIG. 2, the AlN substrate with surface pore defect filling prepared by an embodiment of the present invention includes a polycrystalline AlN substrate 100, pore defects 200 on the AlN substrate 100, a first AlN film 300 deposited at a higher deposition rate, and a second AlN film 400 deposited at a lower deposition rate. Both the first AlN film 300 and the second AlN film 400 are deposited for filling the pore defects 200.

### Embodiment 1

A single-side polished polycrystalline aluminum nitride (AlN) substrate was provided, with a thermal conductivity of 182 W·m⁻¹·K⁻¹ and a polished surface central line average roughness (Ra) of 25 nm. The surface was first wiped and cleaned with isopropanol.

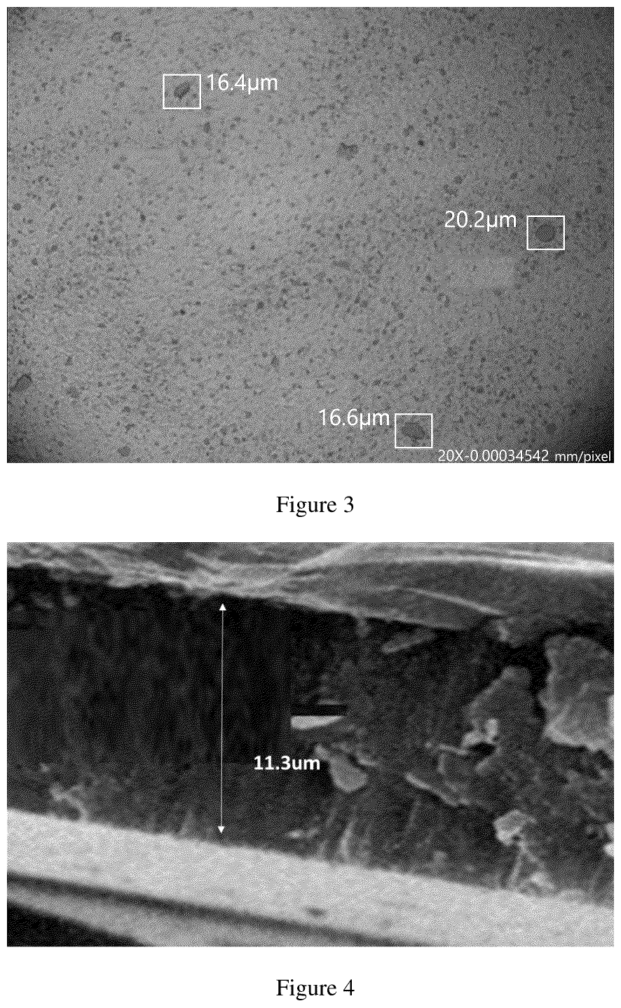

Please refer to FIG. 3, which was a high-magnification optical microscope photo of the surface of the polycrystalline AlN substrate after polishing, according to Embodiment 1 of the present invention. As shown in FIG. 3, many pore defects with sizes ranging from 15 μm to 20 μm can be observed on the polished surface. The surface of the polycrystalline AlN substrate was first cleaned using oxygen ion plasma for 1 minute to remove organic residues and moisture. The polycrystalline AlN substrate was then placed into a high-vacuum magnetron sputtering chamber under process conditions of less than 5×10⁻⁸ torr. Using a process power of 1.5 KW, nitrogen gas at a flow rate of 16 sccm, and argon gas at a flow rate of 48 sccm, high-energy ions were generated and sputtered onto the surface of the polycrystalline AlN substrate from an aluminum target, forming a first AlN film to fill the surface pores. The process time was 60 minutes.

Please refer to FIG. 4, which shows a cross-sectional electron microscope photo of the polycrystalline aluminum nitride (AlN) substrate after sputtering the first AlN film according to Embodiment 1 of the present invention. The measured film thickness was approximately 11.3 μm. The polycrystalline AlN substrate with the first AlN film filling the surface pore defects was then subjected to surface thinning and polishing. The process conditions were as follows: first, using CMP80 (a nano-polishing liquid with a primary particle size of approximately 80 nm) at a rotation speed of 50 rpm, a temperature of 20° C., and a processing pressure of 2.5 kg/cm² for 30 minutes; then, using CMP20 (a nano-polishing liquid with a primary particle size of approximately 20 nm) at a rotation speed of 30 rpm, a temperature of 20° C., and a processing pressure of 2 kg/cm² for 10 minutes to remove the AlN film on the substrate surface, leaving the AlN sputtered material within the pores.

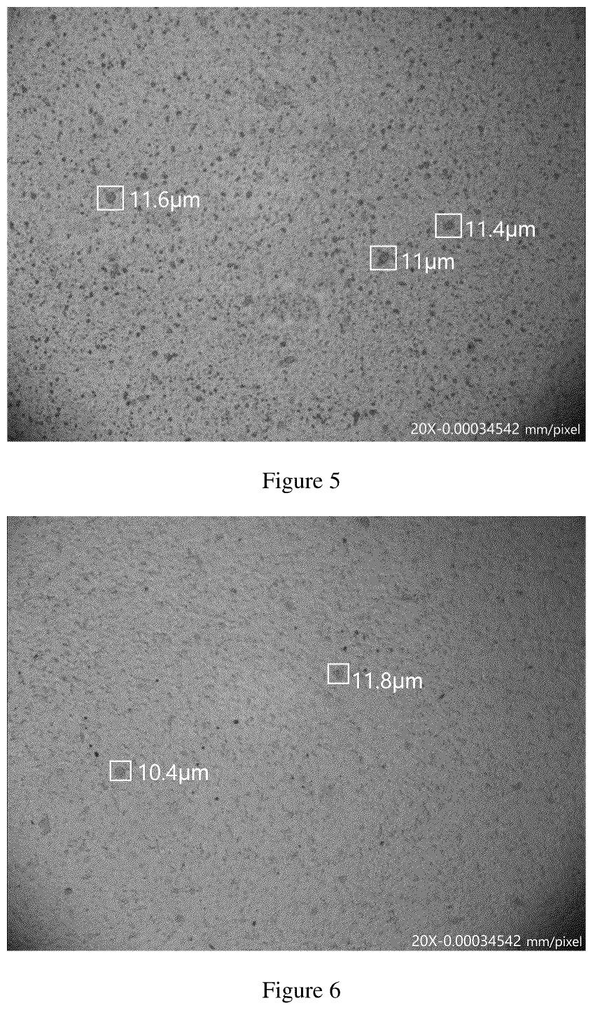

Please refer to FIG. 5, which shows a high-magnification optical microscope photo of the surface after sputtering and polishing the first AlN film according to Embodiment 1 of the present invention. As observed, the first AlN film has filled the surface pore defects of the polycrystalline AlN substrate, with most of the filled pore diameters measuring below 12 μm. The polycrystalline AlN substrate, after filling and planarizing the pore defects with the first AlN film, was subjected to sintering in a nitrogen atmosphere at 1850° C. for 2 hours to enhance the adhesion between the coating AlN film and the substrate within the pores. The sintered substrate was then cooled naturally in the furnace.

Please refer to Table 1. As shown in Table 1, the thermal conductivity and bending-resistant strength of the AlN substrate after filling the pores with the first AlN film and high-temperature sintering were measured to be 186 W·m⁻¹·K⁻¹ and 439 MPa, respectively, showing a slight improvement compared to before sintering. The sintered AlN substrate was first wiped clean with isopropanol and then observed under a high-magnification optical microscope.

Please refer to FIG. 6, which was a high-magnification optical microscope photo of the AlN substrate after filling the pores with the first AlN film and high-temperature sintering according to Embodiment 1 of the present invention. As shown in the FIG. 6, the originally deeper shadowed large pore edges appeared smoother after being filled with the AlN film.

Next, the surface of the polycrystalline AlN substrate was cleaned for 1 minute using oxygen ion plasma to remove organic residues and moisture, and then placed into a high-vacuum magnetron sputtering chamber. Under process conditions of less than 5×10⁻⁸ torr vacuum, using a process power of 1.2 KW, nitrogen gas at a flow rate of 20 sccm, and argon gas at a flow rate of 42 sccm, high-energy ions were generated and sputtered onto the surface of the polycrystalline AlN substrate from an aluminum target, forming a second AlN film. The process time was 40 minutes, and the measured thickness of the filled second AlN film was approximately 8.3 μm.

The polycrystalline AlN substrate with the filled surface pore defects was then subjected to surface thinning and polishing. The process conditions were as follows: first, using CMP80 (a nano-polishing liquid with a primary particle size of approximately 80 nm) at a rotation speed of 50 rpm, a temperature of 20° C., and a processing pressure of 2.5 kg/cm² for 25 minutes; then, using CMP20 (a nano-polishing liquid with a primary particle size of approximately 20 nm) at a rotation speed of 30 rpm, a temperature of 20° C., and a processing pressure of 2 kg/cm² for 10 minutes to remove the AlN film on the substrate surface, leaving the AlN sputtered material within the pores.

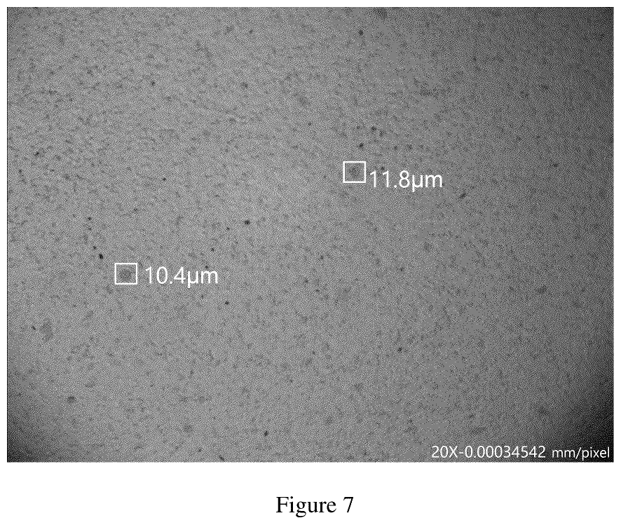

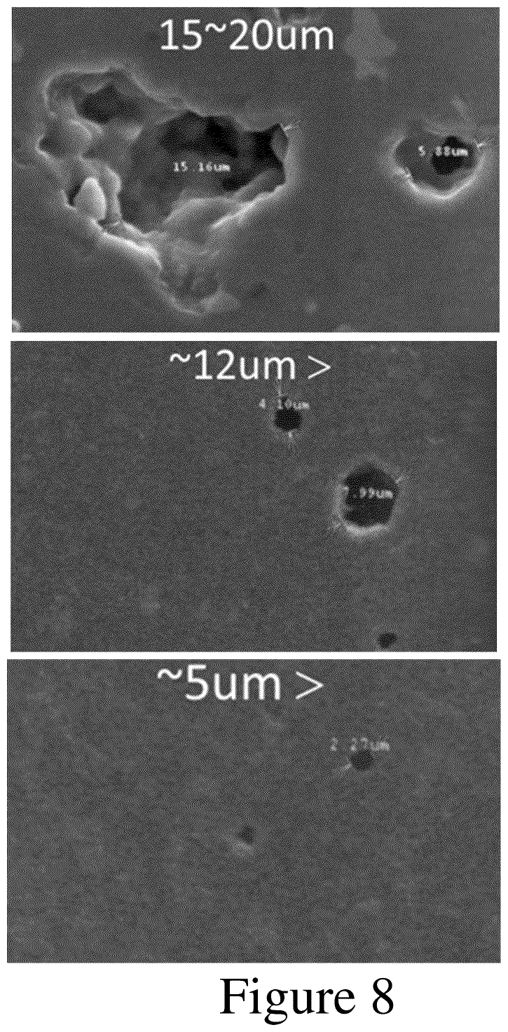

Please refer to FIG. 7 for the high-magnification optical microscope photo of the AlN substrate surface after completing the second AlN film pore filling according to Embodiment 1 of the present invention. As shown in the FIG. 7, the edges of the large pores on the substrate surface were smoother after being filled with the second AlN film, and the filled pore appearance was visible. The majority of the significant pore defect sizes on the substrate surface were measured to be below 5 μm. The differences in the polycrystalline AlN substrate surface porosity during the filling process can be observed using an electron microscope, as shown in FIG. 8. FIG. 8 was a comparative electron microscope observation diagram showing, from left to right, the AlN substrate before pore filling, the AlN substrate after filling and polishing with the first AlN film, and the AlN substrate after filling and polishing with the second AlN film according to Embodiment 1 of the present invention.

### Embodiment 2

A single-side polished polycrystalline aluminum nitride (AlN) substrate was provided, with a thermal conductivity of 178 W·m⁻¹·K⁻¹ and a polished surface central line average roughness (Ra) of 29 nm. The surface was first wiped and cleaned with isopropanol. The surface of the polycrystalline AlN substrate was then cleaned using oxygen ion plasma for 1 minute to remove organic residues and moisture. The substrate was placed into a high-vacuum magnetron sputtering chamber under process conditions of less than 5×10⁻⁸ torr vacuum. Using a process power of 1.5 KW, nitrogen gas at a flow rate of 18 sccm, and argon gas at a flow rate of 42 sccm, high-energy ions were generated and sputtered onto the surface of the polycrystalline AlN substrate from an aluminum target, forming a first AlN film. The process time was 60 minutes, and the measured thickness of the AlN film was approximately 11.9 μm.

The polycrystalline AlN substrate with the first AlN film filling the surface pore defects was then subjected to surface thinning and polishing. The process conditions were as follows: first, using CMP80 (a nano-polishing liquid with a primary particle size of approximately 80 nm) at a rotation speed of 50 rpm, a temperature of 20° C., and a processing pressure of 2.5 kg/cm² for 30 minutes; then, using CMP20 (a nano-polishing liquid with a primary particle size of approximately 20 nm) at a rotation speed of 30 rpm, a temperature of 20° C., and a processing pressure of 2 kg/cm² for 20 minutes to remove the AlN film on the substrate surface, leaving the AlN sputtered material within the pores.

Observation reveals that the first AlN film has filled the surface pore defects of the polycrystalline AlN substrate, with most of the filled pore diameters measuring below 10 μm. The polycrystalline AlN substrate, after filling and planarizing the pore defects with the first AlN film, was subjected to sintering in a nitrogen atmosphere at 1750° C. for 4 hours and then naturally cooled in the furnace.

As shown in Table 1, the thermal conductivity and bending-resistant strength of the AlN substrate after high-temperature sintering were measured to be 185 W·m⁻¹·K⁻¹ and 434 MPa, respectively, showing a slight improvement compared to before sintering. Next, the sintered polycrystalline AlN substrate undergoes the preparation of a second AlN film for pore filling. The surface was first wiped clean with isopropanol, then placed into an oxygen ion plasma chamber for 1 minute of surface cleaning to remove organic residues and moisture. The substrate was then placed into a high-vacuum magnetron sputtering chamber under process conditions of less than 5×10⁻⁸ torr vacuum. Using a process power of 1.2 KW, nitrogen gas at a flow rate of 16 sccm, and argon gas at a flow rate of 40 sccm, high-energy ions were generated and sputtered onto the surface of the polycrystalline AlN substrate from an aluminum target, forming a second AlN film. The process time was 40 minutes, and the measured thickness of the filled second AlN film was approximately 6.1 μm.

The polycrystalline AlN substrate with the filled surface pore defects was then subjected to surface thinning and polishing. The process conditions were as follows: first, using CMP80 (a nano-polishing liquid with a primary particle size of approximately 80 nm) at a rotation speed of 50 rpm, a temperature of 20° C., and a processing pressure of 2.5 kg/cm² for 15 minutes; then, using CMP20 (a nano-polishing liquid with a primary particle size of approximately 20 nm) at a rotation speed of 30 rpm, a temperature of 20° C., and a processing pressure of 2 kg/cm² for 10 minutes to remove the AlN film on the substrate surface, leaving the AlN sputtered material within the pores. High-magnification optical microscope observation reveals that the AlN film has filled most of the pore defects on the surface of the polycrystalline AlN substrate, with the diameters of the filled pore defects mostly measuring below 7 μm.

TABLE 1
Thermal conductivity and bending-resistant strength of AlN
substrates after filling the pores with the first AlN film.

| high-temperature | | | |
|---|---|---|---|
| sintering | Embodiment | 1 | 2 |
| Before | thermal conductivity (W · m⁻¹ · K⁻¹) | 182 | 178 |
| | bending-resistant strength (MPa) | 435 | 426 |
| after | thermal conductivity (W · m⁻¹ · K⁻¹) | 186 | 185 |
| | bending-resistant strength (MPa) | 439 | 434 |

The present invention first reduces the pore sizes caused by lattice defects in polycrystalline ceramic substrates through two layers of film filling and two stages of polishing, thereby enhancing the flatness of the substrate. During the manufacturing process, to ensure the timeliness and reliability of filling the surface pores of the AlN substrate, a two-stage AlN film sputtering filling method is adopted. This approach avoids excessive film thickness from prolonged single-stage sputtering, which can reduce the adhesion to the substrate and cause coating delamination.

Considering timeliness, the first AlN film is sputtered at a higher deposition rate for quick pore filling. A high-temperature sintering step is then introduced to enhance the adhesion and density of the first AlN film within the substrate pores. In contrast, the second AlN film is sputtered at a slower deposition rate, providing a denser film for pore filling, thus improving the density and adhesion of the filled pores on the AlN substrate surface.

After completing the surface film filling, the excess AlN film on the surface outside the pores is removed to minimize the depth difference between the filled pores and the substrate surface. The polycrystalline AlN substrate, after pore filling, shows better thermal conductivity compared to glass and polymer substrates. It also offers cost advantages over high thermal conductivity single-crystal ceramic substrates and better insulation compared to metal substrates. The improved surface flatness of the substrate makes it more suitable for high-power light-emitting device reflector bases, providing competitive advantages in high thermal conductivity, high reflectivity, and low cost. Additionally, the reduced pore sizes on the filled substrate surface make it more suitable for thin, miniaturized insulating circuit substrate development in high-power electronic product applications, enhancing the added value of the products and expanding the potential application fields.

The above embodiments are merely illustrative of the characteristics and effectiveness of the present invention and are not intended to limit the scope of the substantial technical content of the invention. Any person skilled in the art can make modifications and changes to the above embodiments without departing from the spirit and scope of the invention. Therefore, the scope of protection of the present invention should be defined by the following claims.

1. A method for preparing AlN substrate, comprising:
(A) providing a surface-polished polycrystalline aluminum nitride (AlN) substrate having a thermal conductivity of at least 170 W·m⁻¹·K⁻¹;
(B) performing a first surface pore-filling step by forming a first AlN film on a surface of the AlN substrate to fill lattice defect pores on the surface of the AlN substrate, wherein the first AlN film is formed by plasma for reactive sputtering and the plasma is formed by a magnetron sputtering equipment with an aluminum (Al) target, nitrogen gas, and argon gas;
(C) removing the first AlN film formed in step (B) by thinning and polishing to leave filled portions within the lattice defect pores to form a planar AlN substrate;
(D) sintering the planar AlN substrate at a temperature ranging from 1750 to 1850° C. to enhance the adhesion of the AlN film within the lattice defect pores with the substrate;
(E) performing a second surface pore-filling step by forming a second AlN film on the sintered AlN substrate; and
(F) removing the second AlN film formed in step (E) by thinning and polishing to leave filled portions within the lattice defect pores to form a final AlN substrate, wherein surface pore sizes are reduced to a diameter of 5 μm or less.

2. The method of claim 1, wherein the surface-polished polycrystalline aluminum nitride (AlN) substrate in step (A) is prepared by a doctor blade forming method or a sintering and cutting forming method.

3. The method of claim 1, wherein the surface-polished polycrystalline AlN substrate in step (A) has a central line average roughness (Ra) of 20-30 nm.

4. The method of claim 1, further comprising the following steps performed before step (B):
(1) wiping the surface-polished polycrystalline AlN substrate with a solvent selected from acetone, alcohol, or isopropanol to remove surface dirt; and
(2) removing organic residues and moisture from the surface of the polycrystalline AlN substrate using oxygen ion plasma, wherein the oxygen ion plasma is generated by reactive ion etching (RIE) or inductively coupled plasma etching (ICP).

5. The method of claim 1, wherein the plasma for preparing the first AlN film in step (B) is formed from the nitrogen gas, at a flow rate of 16-20 sccm, and the argon gas, at a flow rate of 40-48 sccm, under a vacuum with a pressure less than 5×10-8 torr and using a power of 1.5 KW, and then the plasma reacts with the Al target for 30-90 minutes to form the first AlN film with a thickness of 6-12 μm on the surface of the polycrystalline AlN substrate.

6. The method of claim 1, wherein the thinning and polishing in step (C) or step (F) is performed by chemical mechanical polishing or physical mechanical polishing.

7. The method of claim 1, wherein the thinning and polishing in step (C) or step (F) for removing the first or second aluminum nitride film on the substrate surface is performed under conditions comprising:
using CMP80 (a nano-polishing liquid with a primary particle size of approximately 80 nm) to polish at a rotation speed of 40-60 rpm, a temperature of 20° C., and a processing pressure of 2.5 kg/cm² for 10-60 minutes; then,
using CMP20 (a nano-polishing liquid with a primary particle size of approximately 20 nm) to polish at a rotation speed of 20-40 rpm, a temperature of 20° C., and a processing pressure of 2 kg/cm² for 10-60 minutes.

8. The method of claim 1, wherein the sintering in step (D) is performed under a nitrogen atmosphere, and a holding time of 2-4 hours, and then the sintered AlN substrate is cooled by natural furnace cooling.

9. The method of claim 1, wherein a plasma for preparing the second AlN film in step (E) is formed from the nitrogen gas, at a flow rate of 16-20 sccm, and the argon gas, at a flow rate of 40-42 sccm, under a vacuum with a pressure less than 5×10⁻⁸ torr and using a power of 1.0-1.2 KW, and then the plasma reacts with the Al target for 30-60 minutes to form the second AlN film with a thickness of 5-10 μm on the surface of the polycrystalline AlN substrate.
